(19) United States
(12) Patent Application Publication
(10) Pub. No.: US 2025/0255151 A1
(43) Pub. Date: Aug. 7, 2025

(54) DISPLAY DEVICE HAVING A SENSOR PART AND ELECTRONIC DEVICE INCLUDING THE SAME

(71) Applicant: SAMSUNG DISPLAY CO., LTD., Yongin-si (KR)

(72) Inventors: OHJUNE KWON, Yongin-si (KR); SOOYOUN KIM, Yongin-si (KR); SANGYEON HWANG, Yongin-si (KR)

(21) Appl. No.: 19/008,080

(22) Filed: Jan. 2, 2025

(30) Foreign Application Priority Data
Feb. 1, 2024 (KR) 10-2024-0015999

(51) Int. Cl. H10K 59/80; G06V 40/13; H10K 102/00

(52) U.S. Cl. CPC H10K 59/873; G06V 40/1306; H10K 2102/311

(57) ABSTRACT

A display device includes a display panel having an exterior facing surface, a first coating layer disposed on the display panel opposite the exterior facing surface and defining an opening, a second coating layer disposed on the first coating layer and in the opening, and a sensor part disposed on the second coating layer opposite the first coating layer.

### CROSS-REFERENCE TO RELATED APPLICATION

This application claims priority under 35 U.S.C. § 119 to Korean Patent Application No. 10-2024-0015999, filed on Feb. 1, 2024, in the Korean Intellectual Property Office, the content of which is herein incorporated by reference in its entirety.

### BACKGROUND

### 1. Technical Field

The present disclosure relates to a display device and an electronic device. More specifically, the present disclosure relates to a display device that includes a sensor part and the electronic device.

### 2. Discussion of Related Art

Biometric sensors may be used to acquire biometric information (e.g., a fingerprint, iris pattern, etc.) of a user. The biometric information may be used to perform a user authentication operation. Accurate biometric information may lead to improved user authentication.

### SUMMARY

Embodiments provide to a display device with an improved display quality.

Embodiments provide to a display device including a sensor part disposed on coating layers and having an improved light leakage characteristic.

Embodiments provide to an electronic device including the display device.

A display device according to an embodiment of the present disclosure includes a display panel having an exterior facing surface, a first coating layer disposed on the display panel opposite the exterior facing surface and defining an opening, a second coating layer disposed on the first coating layer and in the opening, and a sensor part disposed on the second coating layer opposite the first coating layer.

In an embodiment, the first coating layer may have a first modulus and the second coating layer may have a second modulus greater than the first modulus.

In an embodiment, the second modulus may be between about 1.2 times and about 10,000 times the first modulus.

In an embodiment, the first coating layer may include at least one of an ultraviolet photoinitiator or a thermal initiator.

In an embodiment, the second coating layer may include an ultraviolet photoinitiator.

In an embodiment, a sidewall of the opening may have an inclination in a cross-sectional view.

In an embodiment, the opening may have a trapezoidal shape in a cross-sectional view.

In an embodiment, the opening in the first coating layer may expose a portion of the display panel, and the second coating layer may be disposed on the display panel exposed in the opening, wherein the opening may include a first opening surface disposed on the display panel and having a first area in a plan view and a second opening surface disposed opposite the first opening surface and having a second area larger than the first area in a plan view.

In an embodiment, the display device may include a window layer disposed on the exterior facing surface of the display panel, wherein the opening may overlap the sensor part in a plan view.

In an embodiment, a planar area in which the first coating layer contacts the second coating layer may be larger than a planar area in which the first coating layer contacts the display panel.

A display device according to an embodiment of the present disclosure includes window layer, a display panel disposed on the window layer and including a plurality of sensor recognition areas, a first coating layer disposed on a lower surface of the display panel opposite the window layer and defining a plurality of openings, a second coating layer disposed on the first coating layer and in the plurality of openings, and a plurality of sensor parts disposed on a lower surface of the second coating layer opposite the first coating layer and overlapping the plurality of openings in a plan view respectively.

In an embodiment, the first coating layer may have a first modulus and the second coating layer has a second modulus greater than the first modulus.

In an embodiment, the second modulus may be between about 1.2 times and about 10,000 times the first modulus.

In an embodiment, the first coating layer may include at least one of a first ultraviolet photoinitiator or a thermal initiator, and the second coating layer may include a second ultraviolet photoinitiator.

In an embodiment, a sidewall of each of opening the plurality of openings may have an inclination in a cross-sectional view.

In an embodiment, each opening of the plurality of openings may include a first opening surface disposed on the display panel and having a first area in a plan view and a second opening surface disposed opposite the first opening surface and having a second area larger than the first area in a plan view.

In an embodiment, the plurality of openings may overlap the plurality of sensor parts in a plan view respectively.

In an embodiment, a planar area in which the first coating layer contacts the second coating layer may be larger than a planar area in which the first coating layer contacts the display panel.

A display device according to embodiments of the present disclosure includes a display panel having an exterior facing surface, a first coating layer having a first modulus and disposed on the display panel opposite the exterior facing surface and defining an opening exposing the display panel and having a sidewall having a slope in a cross-sectional view, a second coating layer having a second modulus greater than the first modulus and disposed on the first coating layer and the display panel exposed in the opening, and a sensor part disposed on the second coating layer opposite the first coating layer and overlapping the opening.

In an embodiment, the opening includes a first opening surface disposed on the display panel and having a first area in a plan view, and a second opening surface disposed opposite the first opening surface and having a second area larger than the first area in a plan view, wherein the sensor part is a biometric sensor for detecting a characteristic of a finger of a user, and the display device further includes a printed circuit board disposed on disposed on the second coating layer opposite the first coating layer, wherein the printed circuit board is disposed outside of the second opening surface, and a connection pattern electrically connecting the printed circuit board and the sensor part.

An electronic device according to an embodiment of the present disclosure includes a display device and a processor configured to drive the display device, and the display device includes a display panel having an exterior facing surface, a first coating layer disposed on the display panel opposite the exterior facing surface and defining an opening, a second coating layer disposed on the first coating layer and in the opening, and a sensor part disposed on the second coating layer opposite the first coating layer.

A display device according to embodiments of the present disclosure may include a window layer, a display panel disposed below the window layer, a first coating layer disposed below the display panel and defining an opening, and having a first modulus. It may include a second coating layer disposed below the first coating layer and having a second modulus different than the first modulus, and a sensor part disposed below the second coating layer.

A quality of the user's touch signal may be improved by disposing the sensor part on the second coating layer and overlapping the opening in the first coating layer in a plan view, and wrinkles may be prevented or inhibited by disposing the second coating layer between the first coating layer and the sensor part.

In addition, the opening in the first coating layer may have a slope in a direction of the display panel, and an amount of light flowing into the display panel may be reduced, reducing an occurrence of side effects in the display device, and providing users with an improved the display device.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a plan view showing a display device according to an embodiment of the present disclosure.

FIG. 2 is a rear view showing an embodiment of a rear surface of the display device of FIG. 1.

FIG. 3 is a cross-sectional view taken along line I-I′ of FIG. 1.

FIG. 4 is a cross-sectional view showing an embodiment of display panel of FIG. 3.

FIG. 5 is a cross-sectional view taken along line II-II′ of FIG. 1.

FIG. 6 is a cross-sectional view showing an embodiment in which a user uses the display device of FIG. 5.

FIGS. 7, 8, 9, 10, 11, and 12 are views showing a manufacturing process of attaching a sensor part to the display device.

FIG. 13 is a rear view showing another embodiment of a rear surface of the display device of FIG. 1.

FIG. 14 is block-diagram for showing an electronic device according to an embodiment of the disclosure.

FIG. 15 is schematic views for showing the electronic device according to various embodiments of FIG. 14.

### DETAILED DESCRIPTION

Illustrative, non-limiting embodiments will be more clearly understood from the following detailed description in conjunction with the accompanying drawings. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the

spirit and scope of the inventive concepts. Like reference numerals or symbols refer to like elements throughout.

In the drawings, the thicknesses, the ratios, and the dimensions of the elements may be exaggerated for effective description of the technical contents.

In this specification, a plane may be defined by a first direction D1 and a second direction D2 that intersects the first direction D1. For example, the second direction D2 may be perpendicular to the first direction D1. In addition, a third direction D3 may be a normal direction to the plane defined by the first direction D1 and the second direction D2. That is, the third direction D3 may be perpendicular to the plane formed by the first direction D1 and the second direction D2.

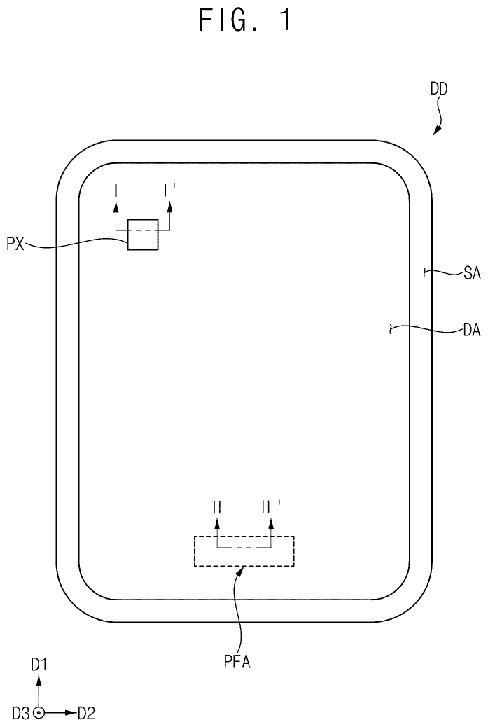

FIG. 1 is a plan view showing a display device according to an embodiment of the present disclosure.

Referring to FIG. 1, a display device DD may include a display area DA and a peripheral area SA. The peripheral area SA may be disposed around at least a portion of the display area DA. The display area DA may be surrounded by the peripheral area SA.

The display area DA may be an area that may display an image. The image may be disposed by the display area DA by generating light or adjusting a transmittance of light provided from an external light source. The peripheral area SA may be an area that does not display an image. However, embodiments of the present disclosure are not limited to this, and at least a portion of the peripheral area SA may display an image.

A pixel PX may be disposed in the display area DA. A plurality of pixels PX may be disposed in the display area DA in the first direction D1 and/or the second direction D2. Each pixel PX may emit light. The plurality of pixels PX may emit light and generate visual images that may be viewed by a user of the display device DD.

The display device DD may include a sensor recognition area PFA. The sensor recognition area PFA may be disposed on a side of the display area DA. The sensor recognition area PFA may be an area where the display device DD may send and receive signals by recognizing motion or touch of a user. A plurality of sensor recognition areas PFA may be disposed in the display area DA. That is, a plurality of sensor recognition areas PFA may be disposed spaced apart from each other in the display area DA.

Biometric sensors for fingerprint recognition may be divided into optical, ultrasonic, and electrostatic types depending on a method of acquiring fingerprint information. In an embodiment, a sensor recognition area PFA may be an area for acquiring a fingerprint of the user. For example, the sensor recognition area PFA may be an area for acquiring an optical image of a fingerprint.

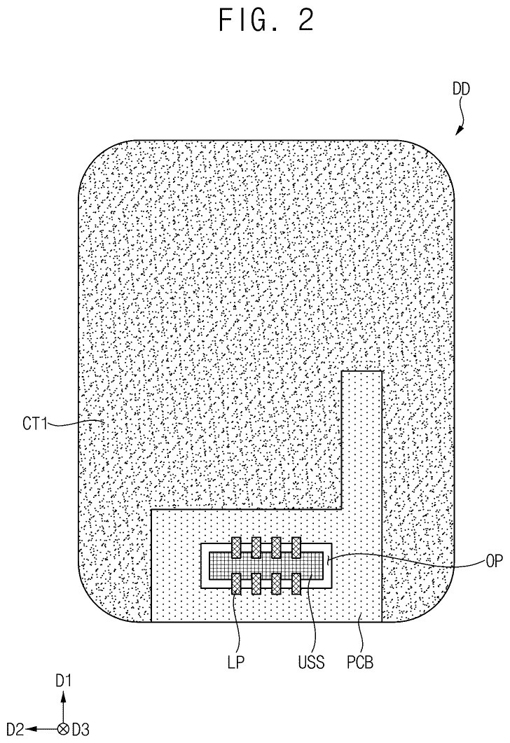

FIG. 2 is a rear view showing an embodiment of a rear surface of the display device of FIG. 1.

Referring to FIG. 2, the display device DD may include a first coating layer CT1, a printed circuit board PCB, a sensor part USS, and a connection pattern LP.

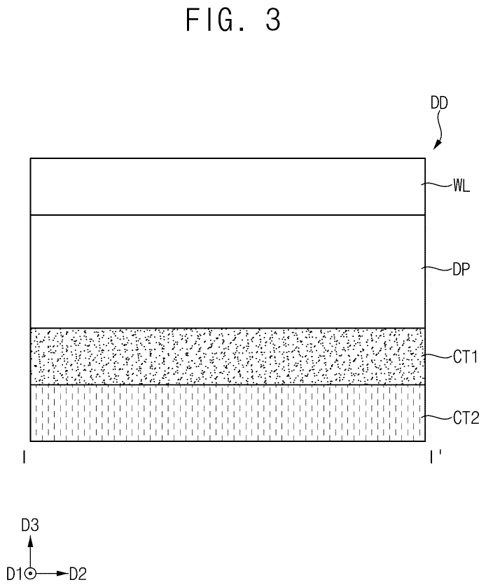

The first coating layer CT1 may be disposed on a rear surface of the display device DD. The first coating layer CT1 may be entirely disposed on a rear surface of the display device DD. An opening OP may be defined in the first coating layer CT1. The first coating layer CT1 and the opening OP will be described in detail with reference to FIGS. 3, 4, and 5.

The printed circuit board PCB may be disposed on a back surface of the first coating layer CT1. The printed circuit board PCB may include a driving chip capable of driving the display device DD. Accordingly, the printed circuit board PCB may be electrically connected to the display device DD and may drive the display device DD.

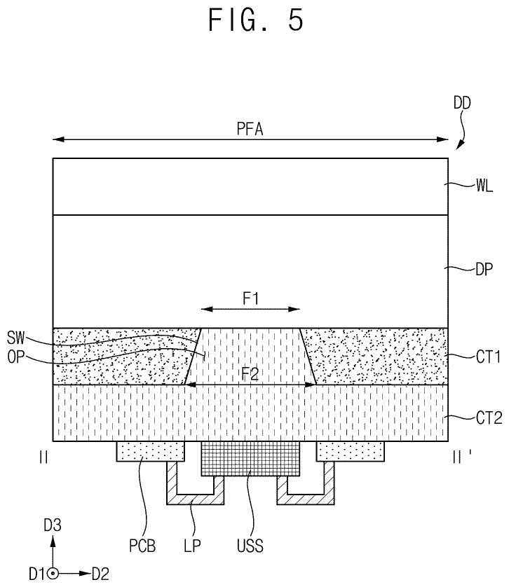

The sensor part USS may be disposed overlapping with the opening OP in a plan view. The sensor part USS may be disposed entirely within the opening OP in a plan view. The sensor part USS may transmit a touch driving signal and may receive a sensing signal. That is, the sensing signal may be a reflected portion of the touch driving signal. The sensor part USS will be described in detail with reference to FIG. 5.

The printed circuit board PCB and the sensor part USS may be electrically connected through the connection pattern LP. That is, the touch driving signal transmitted from the sensor part USS and the sensing signal received from the sensor part USS may be electrically transmitted to the printed circuit board PCB by the connection pattern LP.

FIG. 3 is a cross-sectional view taken along line I-I′ of FIG. 1.

Referring to FIG. 3, the display device DD may include a window layer WL, a display panel DP, the first coating layer CT1, and a second coating layer CT2.

The window layer WL may include a substantially transparent material. For example, the window layer WL may be glass or plastic. However, embodiments of the present disclosure are not limited thereto.

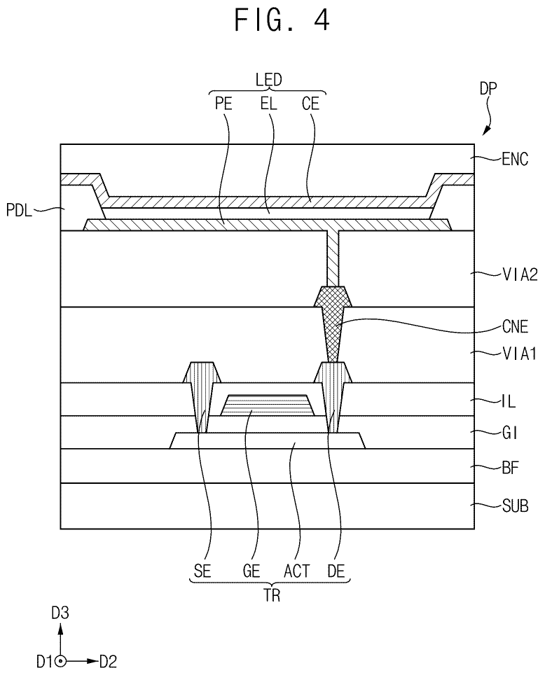

The display panel DP may be disposed below the window layer WL. The display panel DP may be disposed on a lower surface of the window layer WL. For example, the display panel DP may include an exterior facing surface on which the window layer WL may be disposed. The display panel DP may include at least one of an organic light emitting display panel or an inorganic light emitting display panel. However, embodiments of the present disclosure are not limited thereto. The display panel DP will be described in detail later with reference to FIG. 4.

The first coating layer CT1 may be disposed below the display panel DP. The first coating layer CT1 may be disposed on a lower surface of the display panel DP, opposite the exterior facing surface of the display panel DP and the window layer WL. The first coating layer CT1 may include a resin containing black dye. That is, the first coating layer CT1 may be a light blocking layer. For example, the first coating layer CT1 may include at least one of an ultraviolet (UV) photoinitiator or a thermal initiator. However, embodiments of the present disclosure are not limited thereto.

In an embodiment, the first coating layer CT1 may have a first modulus. The first modulus may be between about 0.05 MPa and about 5 MPa. Preferably, the first modulus may be between about 0.05 MPa and about 2 MPa. However, embodiments of the present disclosure are not limited thereto.

The second coating layer CT2 may be disposed below the first coating layer CT1. The second coating layer CT2 may be disposed on a lower surface of the first coating layer CT1, opposite the display panel DP. The second coating layer CT2 may be a coating layer that protects the display device DD. The second coating layer CT2 may be a coating layer that protects the display device DD from impact.

In an embodiment, the second coating layer CT2 may have a second modulus that is different from the first modulus. The second modulus may be between about 0.1 MPa and about 20,000 MPa. Preferably, the second modulus may be between about 0.1 MPa and about 10,000 MPa. For example, the second coating layer CT2 may include a UV photoinitiator. However, embodiments of the present disclosure are not limited thereto.

In an embodiment, the second modulus may be between about 1.2 times and 10,000 times the first modulus. Preferably, the second modulus may be between about 1.2 times and 5000 times the first modulus. However, embodiments of the present disclosure are not limited thereto. In an embodiment, in a case where the second coating layer CT2 has a greater modulus than the first coating layer CT1, wrinkles of the first coating layer CT1 on a back of the display device DD may be prevented or inhibited.

In an embodiment, the first coating layer CT1 may include a first UV photoinitiator and the second coating layer CT2 may include a second UV photoinitiator. The first UV photoinitiator and the second UV photoinitiator may be different photoinitiators. The first UV photoinitiator and the second UV photoinitiator may be a same photoinitiator with different values of modulus. In an embodiment, a modulus of a UV photoinitiator may be adjusted by a level of irradiation during polymerization, and the modulus value(s) of the first UV photoinitiator and the second UV photoinitiator may be individually adjusted.

FIG. 4 is a cross-sectional view showing an embodiment of display panel of FIG. 3.

Referring to FIGS. 1, 2, 3, and 4, the display panel DP may include a substrate SUB, a buffer layer BF, a gate insulating layer GI, a transistor TR, an interlayer insulating layer IL, a connecting electrode CNE, a first via layer VIA1, a second via layer VIA2, a light emitting diode LED, a pixel defining layer PDL, and an encapsulation layer ENC. The substrate SUB, the buffer layer BF, the gate insulating layer GI, the interlayer insulating layer IL, the first via layer VIA1, the second via layer VIA2, the pixel defining layer PDL, and the encapsulation layer ENC may be sequentially disposed in a stack.

The transistor TR may include an active layer ACT, a gate electrode GE, a source electrode SE, and a drain electrode DE. The light emitting diode LED may include a pixel electrode PE, a light emitting layer EL, and a common electrode CE.

The substrate SUB may include a glass substrate, a metal substrate, or a plastic substrate. However, embodiments of the present disclosure are not limited to these examples, and the substrate SUB may be an inorganic layer, an organic layer, or a composite material layer.

The buffer layer BF may be disposed on the substrate SUB. The buffer layer BF may be disposed on an upper surface of the substrate SUB. The buffer layer BF may prevent or inhibit impurities such as oxygen or moisture from penetrating into an upper portion of the substrate SUB. The buffer layer BF may include an inorganic insulating material.

The active layer ACT may be disposed on the buffer layer BF. The active layer ACT may be disposed on an upper surface of the buffer layer BF. The active layer ACT may include an oxide semiconductor, a silicon semiconductor, or an organic semiconductor. For example, the oxide semiconductor may include at least one oxide from indium (In), gallium (Ga), tin (Sn), zirconium (Zr), vanadium (V), hafnium (Hf), cadmium (Cd), germanium (GE), chromium (Cr), titanium (Ti), or zinc (Zn). The silicon semiconductor may include amorphous silicon or polycrystalline silicon. However, embodiments of the present disclosure are not limited to these examples. The active layer ACT may include a source region, a drain region, and a channel region disposed between the source region and the drain region.

The gate insulating layer GI may be disposed on the buffer layer BF. Specifically, the gate insulating layer GI may cover the active layer ACT disposed on the buffer layer BF. The gate insulating layer GI may include an inorganic insulating material. In an embodiment, the gate insulating layer GI may be formed entirely in the display area DA and the peripheral area SA.

The gate electrode GE may be disposed on the gate insulating layer GI. The gate electrode GE may at least partially overlap the channel region of the active layer ACT. The gate electrode GE may include a conductive material such as a metal, alloy, conductive metal nitride, conductive metal oxide, or transparent conductive material. Examples of the conductive material that may be used in the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloy containing aluminum, alloy containing silver, alloy containing copper, alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), or indium zinc oxide (IZO). However, embodiments of the present disclosure are not limited to these examples. These example materials may be used alone or in combination with each other. Alternatively, the gate electrode GE may have a single-layer structure or a multi-layer structure including a plurality of conductive layers.

The interlayer insulating layer IL may be disposed on the gate electrode GE. Specifically, the interlayer insulating layer IL may be disposed on the gate insulating layer GI and cover the gate electrode GE disposed on the gate insulating layer GI. The interlayer insulating layer IL may include an inorganic insulating material.

The source electrode SE and the drain electrode DE may be disposed on the interlayer insulating layer IL. Each of the source electrode SE and the drain electrode DE may be connected to the active layer ACT. For example, the source electrode SE may contact the source region of the active layer ACT, and the drain electrode DE may contact the drain region of the active layer ACT. Each of the source electrode SE and the drain electrode DE may include a conductive material. The active layer ACT, the gate electrode GE, the source electrode SE, and the drain electrode DE may form the transistor TR.

The first via layer VIA1 may be disposed on the source electrode SE and the drain electrode DE. Specifically, the first via layer VIA1 may be disposed on an upper surface of the interlayer insulating layer IL and cover the source electrode SE and the drain electrode DE disposed on the interlayer insulating layer IL. The first via layer VIA1 may include an organic insulating material. In an embodiment, the first via layer VIA1 may be formed in the display area DA and a portion of the peripheral area SA adjacent to the display area DA. The first via layer VIA1 may be form on less than an entirety of the peripheral area SA adjacent to the display area DA.

The connection electrode CNE may be disposed on the first via layer VIA1. The connection electrode CNE may be disposed on an upper surface of the first via layer VIA1. The connection electrode CNE may transmit a signal transmitted from the transistor TR to the light emitting diode LED. The connection electrode CNE may include metal, alloy, metal nitride, conductive metal oxide, or transparent conductive material. These may be used alone or in combination with each other. However, embodiments of the present disclosure are not limited thereto.

The second via layer VIA2 may be disposed on the connection electrode CNE. The second via layer VIA2 may be disposed on an upper surface of the connection electrode CNE. Specifically, the second via layer VIA2 may be disposed on the first via layer VIA1 and cover the connection electrode CNE. The second via layer VIA2 may include substantially a same material as the first via layer VIA1.

The pixel electrode PE may be disposed on the second via layer VIA2. The pixel electrode PE may be disposed on an upper surface of the second via layer VIA2. The pixel electrode PE may include a conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. The pixel defining layer PDL may be disposed on a sidewall of the pixel electrode PE. The pixel defining layer PDL may be disposed on a portion of an upper surface of the pixel electrode PE. For example, the pixel defining layer PDL may expose at least a portion of the pixel electrode PE. The pixel defining layer PDL may include an inorganic insulating material or an organic insulating material.

The light emitting layer EL may be disposed on the pixel electrode PE. Specifically, the light emitting layer EL may be disposed within an opening defined by the pixel defining layer PDL. That is, the light emitting layer EL may be surrounded by the pixel defining layer PDL. The pixel defining layer PDL may be disposed on a sidewall of the light emitting layer EL. The light emitting layer EL may include at least one of organic light emitting material and/or quantum dots. However, embodiments of the present disclosure are not limited thereto.

The common electrode CE may be disposed on the light emitting layer EL. The common electrode CE may also be disposed on the pixel defining layer PDL. The common electrode CE may be disposed on an upper surface of the light emitting layer EL and an upper surface of the pixel defining layer PDL. That is, the common electrode CE may be continuously disposed on the light emitting layer EL and the pixel defining layer PDL. The common electrode CE may include a conductive material. The light emitting layer EL may emit light based on voltage difference between the pixel electrode PE and the common electrode CE.

The encapsulation layer ENC may be disposed on the common electrode CE. The encapsulation layer ENC may be disposed on an upper surface of the common electrode CE. The encapsulation layer ENC may include at least one inorganic encapsulation layer or at least one organic encapsulation layer. In an embodiment, the inorganic encapsulation layer and the organic encapsulation layer may be alternately disposed. For example, the organic encapsulation layer may include a cured polymer such as polyacrylate, epoxy resin, or silicone resin. For example, the inorganic encapsulation layer may include silicon oxide, silicon nitride, silicon carbide, aluminum oxide, tantalum oxide, hafnium oxide, zirconium oxide, or titanium oxide. However, embodiments of the present disclosure are not limited thereto.

FIG. 5 is a cross-sectional view taken along line II-II′ of FIG. 1. Configurations described with reference to FIG. 5 may be substantially a same as those described with reference to FIG. 3, and may include further descriptions of the sensor part USS, the printed circuit board PCB, and the connection pattern LP. Repetitive descriptions thereof may be omitted or simplified.

Referring to FIG. 5, within in the sensor recognition area PFA, the display device DD may include the window layer WL, the display panel DP, the first coating layer CT1, the second coating layer CT2, the sensor part USS, the printed circuit board PCB, and the connection pattern LP.

The first coating layer CT1 may be disposed below the display panel DP. The first coating layer CT1 may be disposed on a lower surface of the display panel DP. The first coating layer CT1 may include the opening OP exposing a portion of the display panel DP. That is, the opening OP may be disposed in the first coating layer CT1 that overlaps the sensor recognition area PFA in a plan view. Accordingly, the opening OP may overlap the sensor recognition area PFA in a plan view and may be an area through which sensing signals (e.g., the touch driving signal and/or the sensing signal) may pass.

In an embodiment, the opening OP may have a shape for controlling a passage of light therethrough. For example, the opening OP may have a trapezoidal shape in a cross-sectional view. That is, the opening OP may have a trapezoidal shape whose planar area becomes narrower in the third direction D3. The opening OP may be relatively narrow at the display panel DP and relatively wide at the second coating layer CT2. That is, the opening OP may have a shape with a sidewall SW having a slope in a cross-sectional view.

In an embodiment, an area through which light flowing in the third direction D3 may pass may narrow in the third direction D3, that is in a direction toward the display panel DP, and an amount of light flowing into the display device DD may be reduced as compared to an opening having sidewalls normal to the plane defined by the first direction D1 and the second direction D2. In an example in which the opening OP has a trapezoidal shape, the amount of light leakage due to the opening OP or light passing through the display device DD from a backside of the display device due to the opening OP may be reduced. However, embodiments of the present disclosure are not limited thereto. The opening OP may have a trapezoidal shape whose planar area increases in the third direction D3.

For example, the opening OP may include a first opening surface F1 having a first area in a plan view and a second opening surface F2 having a second area in a plan view. The first opening surface F1 may be spaced apart from the second opening surface F2 in the third direction D3. For example, the first opening surface F1 may be disposed on the display panel DP and the second opening surface F2 may be disposed on the second coating layer CT2. The first area of the first opening surface F1 may be less than the second area of the second opening surface F2. In a case that the second opening surface F2 has a larger contact area than the first opening surface F1, a contact area in which the first coating layer CT1 and the second coating layer CT2 contact each other may be larger than a contact area in which the first coating layer CT1 and the display panel DP contact each other. Accordingly, the opening OP may have a trapezoidal shape in a cross-sectional view. For another example, the first opening surface F1 may be larger than the second opening surface F2.

The second coating layer CT2 may be disposed below the first coating layer CT1. The second coating layer CT2 may be disposed on the lower surface of the first coating layer CT1. Specifically, the second coating layer CT2 may be disposed below the first coating layer CT1 and fill the opening OP. The second coating layer CT2 may be disposed on sidewalls SW of the opening OP. The second coating layer CT2 may directly contact the display panel DP exposed by the opening OP. That is, the second coating layer CT2 may directly contact the substrate (e.g., the substrate SUB in FIG. 4) of the display panel DP.

In an embodiment, the second coating layer CT2 may include a transparent material. Accordingly, when the display device DD is viewed in the third direction D3 and the second coating layer CT2 is transparent, and the first coating layer CT1 may be visible to a user. In addition, in a case that the second coating layer CT2 is transparent, a visual confirmation may be obtained that the sensor part USS overlaps the opening OP when attaching the sensor part USS to the second coating layer CT2. For example, the sensor part USS may be visually aligned to the opening OP when attaching the sensor part USS to the second coating layer CT2. However, embodiments of the present disclosure are not limited thereto. The second coating layer CT2 may include a translucent material.

The sensor part USS may be disposed below the second coating layer CT2. The sensor part USS may be disposed on a lower surface of the second coating layer CT2. Specifically, the sensor part USS may be disposed below the second coating layer CT2 and may be disposed to overlap the opening OP in a plan view. The sensor part USS may be disposed to overlap the sensor recognition area PFA in a plan view. Accordingly, as users use the display device DD, the sensor part USS may recognize a touch, slide, or drag of a user's interaction in the sensor recognition area PFA. However, embodiments of the present disclosure are not limited thereto, and other interactions are possible.

The printed circuit board PCB may be disposed below the second coating layer CT2. The printed circuit board PCB may be disposed on the lower surface of the second coating layer CT2. For example, as shown in FIG. 2, the printed circuit board PCB may be disposed to surround the sensor part USS in a plan view.

The connection pattern LP may electrically connect the printed circuit board PCB and the sensor part USS. The connection pattern LP may include a conductive material such as a metal. For example, the connection pattern LP may include molybdenum (Mo), aluminum (Al), chromium (Cr), gold (Au), titanium (Ti), nickel (Ni), neodymium (Nd), or copper (Cu). These may be used alone or in combination with each other. However, embodiments of the present disclosure are not limited thereto.

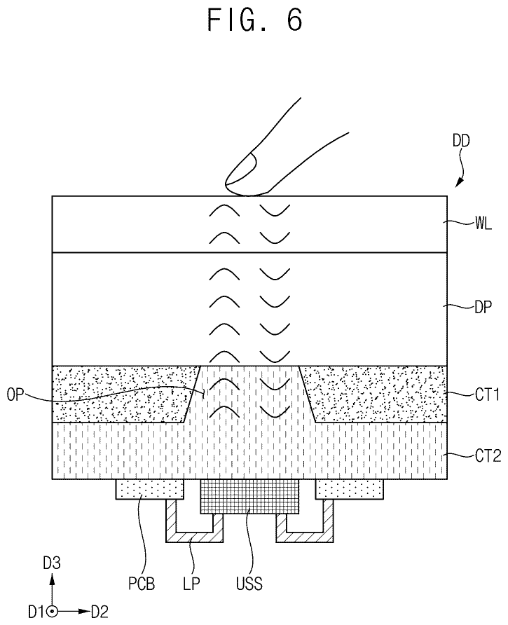

FIG. 6 is a cross-sectional view showing an embodiment in which a user uses the display device of FIG. 5. Configurations described with reference to FIG. 6 are substantially a same as those described with reference to FIG. 5, and repetitive descriptions thereof may be omitted or simplified.

Referring to FIG. 6, the sensor part USS may generate a touch driving signal. The touch driving signal may be transmitted toward the display panel DP in the third direction D3. For example, the touch driving signal generated by the sensor part USS may be at least one of an ultrasonic signal, an infrared signal, or a terahertz signal. However, embodiments of the present disclosure are not limited thereto. The sensor part USS may detect the sensing signal generated when the touch driving signal is reflected by at least a portion of a finger. The sensor part USS may be configured to analyze the detected sensing signal and generate an image to determine the fingerprint. For example, the sensor part USS may be a biometric sensor for detecting a characteristic of the finger of the user, such as an arrangement of ridges forming a fingerprint.

In a case of ultrasound, as a frequency increases, a degree of signal attenuation may increase in low-density materials. Therefore, as the frequency increases, the density of ultrasonic transmission and reception channels may have a significant impact on a quality of the ultrasonic signal. Accordingly, in a case that a density of the second coating layer CT2 through which the touch driving signal and the sensing signal of the sensor part USS pass is high, the touch sensitivity may increase. That is, in the case that the second modulus of the second coating layer CT2 is high, a quality of the touch driving signal and the sensing signal may be improved. For example, the touch driving signal and the sensing signal may be passed through the second coating layer CT2 with a high fidelity. In the case that the first coating layer CT1 having the first modulus includes the opening OP and the signals transmitted and received from the sensor unit USS pass through the second coating layer CT2 having the second modulus, the transmitted and received signals may be measured more accurately.

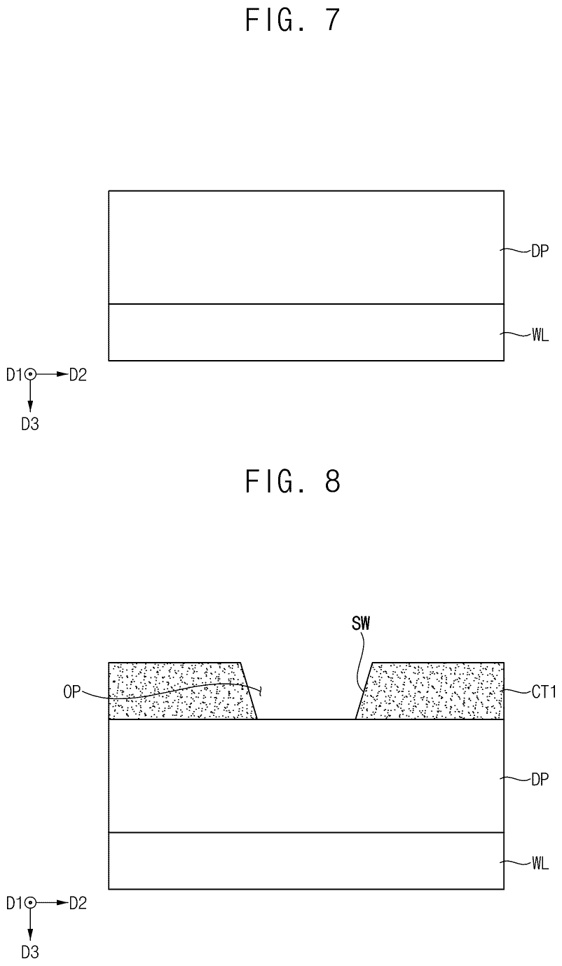

FIGS. 7, 8, 9, 10, 11, and 12 are views showing a manufacturing process of attaching a sensor part to the display device.

Referring to FIG. 7, the display panel DP may be attached to the window layer WL. Specifically, the window layer WL may be disposed on the encapsulation layer (e.g., the encapsulation layer ENC in FIG. 4) of the display panel DP. That is, the window layer WL may be disposed on a first surface of the display panel DP. The window layer WL and the display panel DP may be attached to each other using an optical clear adhesive OCA or an optical clear resin OCR (not shown). However, embodiments of the present disclosure are not limited thereto.

Referring further to FIG. 8, the first coating layer CT1 may be attached to the display panel DP. Specifically, the first coating layer CT1 may be disposed on a substrate of the display panel DP (e.g., the substrate SUB in FIG. 4). That is, the first coating layer CT1 may be disposed on a second surface of the display panel DP opposite the first surface. The first coating layer CT1 may be formed on a backside of the display panel DP using an inkjet device or the like. The backside of the display panel DP may be a same surface as the lower surface of the display panel DP described with reference to FIG. 3. That is, a manufacture of the display device DD may be perform in a flipped configuration, wherein lower surfaces thereof may be disposed upwardly in a direction opposite to the third direction D3. However, embodiments of the present disclosure are not limited thereto.

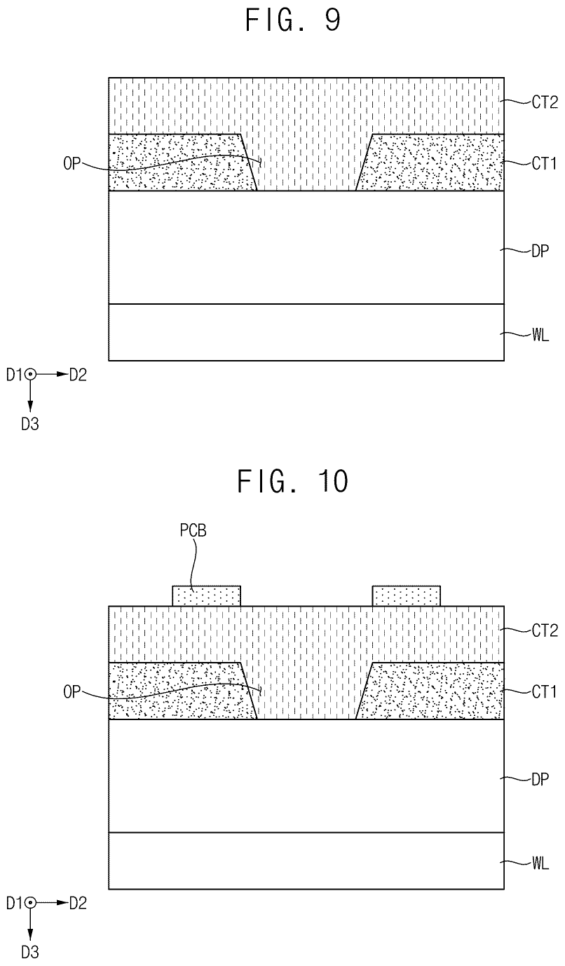

In an embodiment, the opening OP may be defined in the first coating layer CT1. For example, the opening OP may be formed through a selective deposition using the inkjet device. The opening OP may be formed to expose a portion of the display panel DP. The first coating layer CT1 may be formed on the display panel DP and cured. Following the formation of the first coating layer CT1, the second coating layer (e.g., the second coating layer CT2 in FIG. 9) may be formed, for example, by inkjet printing. The first coating layer CT1 may be UV cured and/or heat cured. The opening OP may have a sidewall SW having an inclination in a cross-sectional view. That is, as shown in FIG. 8, the opening OP may have a trapezoidal shape in a cross-sectional view. However, embodiments of the present disclosure are not limited thereto.

Referring further to FIG. 9, the second coating layer CT2 may be disposed on the first coating layer CT1. Specifically, the second coating layer CT2 may be disposed on the display panel DP and may cover the first coating layer CT1. That is, the second coating layer CT2 may be disposed on the lower surface of the first coating layer CT1 opposite the display panel. The second coating layer CT2 may be formed using an inkjet device or the like. The second coating layer CT2 may be UV cured. However, embodiments of the present disclosure are not limited thereto.

In an embodiment, at least a portion of the second coating layer CT2 may directly contact the display panel DP. For example, at least a portion of the second coating layer CT2 may be disposed in the opening OP of the first coating layer CT1 and may contact the display panel DP. A portion of the second coating layer CT2 may be disposed in the opening OP and may have a same shape as the opening OP. For example, a portion of the second coating layer CT2 may be disposed in the opening OP and may have a trapezoidal shape in a cross-sectional view.

Referring further to FIG. 10, the printed circuit board PCB may be formed on the second coating layer CT2. That is, the printed circuit board PCB may be disposed on the lower surface of the second coating layer CT2. The printed circuit board PCB may not overlap the opening OP in a plan view. For example, the printed circuit board PCB may be disposed outside of the second opening surface F2 (see FIG. 5).

In an embodiment, the printed circuit board PCB may overlap a portion of the opening OP in a plan view. For example, the printed circuit board PCB may overlap a portion of the second opening surface F2 (see FIG. 5) the opening OP and may not overlap the first opening surface F1 of the opening OP. For example, the printed circuit board PCB may be disposed outside of the first opening surface F1 (see FIG. 5).

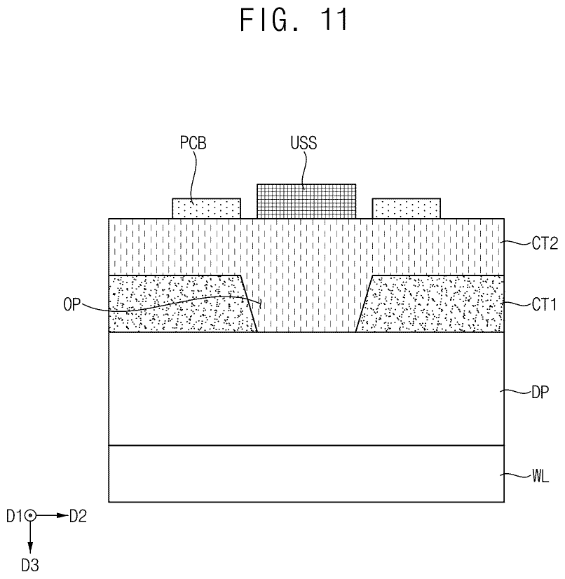

Referring further to FIG. 11, the sensor part USS may be formed on the second coating layer CT2. The printed circuit board PCB may be disposed around at least a portion of the sensor part USS in a plan view. For example, the sensor part USS may be surrounded by the printed circuit board PCB in a plan view. The sensor part USS may be disposed to overlap the opening OP in a plan view. Accordingly, the touch driving signal and/or the sensing signal transmitted from the sensor part USS may pass through the second coating layer CT2.

By disposing the sensor part USS on the second coating layer CT2, a degree of freedom may increase to attach the sensor part USS to the display device DD. For example, a degree of freedom of placement of the sensor part USS may be increased with respect to a location of the opening OP. Accordingly, a yield of the process of attaching the sensor part USS may increase.

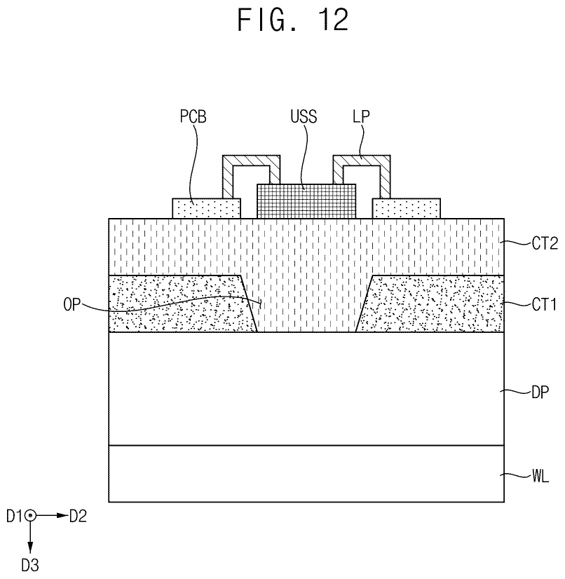

Referring further to FIG. 12, the connection pattern LP connecting the printed circuit board PCB and the sensor part USS may be formed. The connection pattern LP may include a conductor. Accordingly, the sensor part USS and the printed circuit board PCB may be electrically connected.

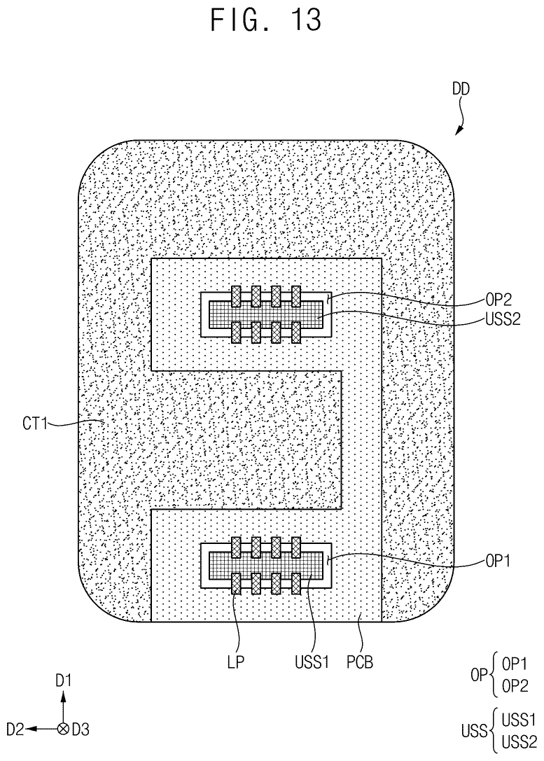

FIG. 13 is a rear view showing another embodiment of a rear surface of the display device of FIG. 1.

Referring to FIG. 13, the display device DD may include a first coating layer CT1 including at least two openings OP. For example, the first coating layer CT1 may include a first opening OP1 and a second opening OP2. However, embodiments of the present disclosure are not limited thereto. For example, three or more openings OP may be disposed in the first coating layer CT1. The first opening OP1 and the second opening OP2 may be disposed spaced apart from each other in the first direction D1. However, embodiments of the present disclosure are not limited thereto. For example, the first opening OP1 and the second opening OP2 may be disposed spaced apart from each other in the second direction D2.

In an embodiment, the sensor part USS may include a first sensor part USS1 and a second sensor part USS2. The first sensor part USS1 may be disposed in the first opening OP1 and the second sensor part USS2 may be disposed in the second opening OP2 in a plan view. Each of the first sensor part USS1 and the second sensor part USS2 may be electrically connected to the printed circuit board PCB through the connection pattern LP.

Inventive concepts of the present disclosure may be applied to a display device and an electronic device including a same. For example, inventive concepts of the present disclosure may be applied to high-resolution smartphones, mobile phones, smart pads, smart watches, tablet PCs, vehicle navigation systems, televisions, computer monitors, or laptops.

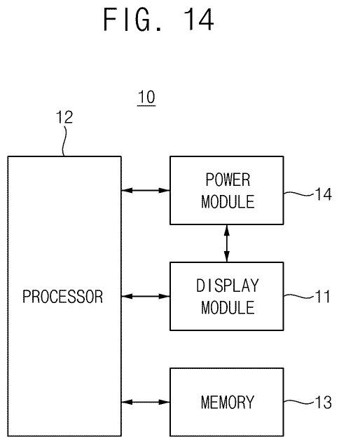

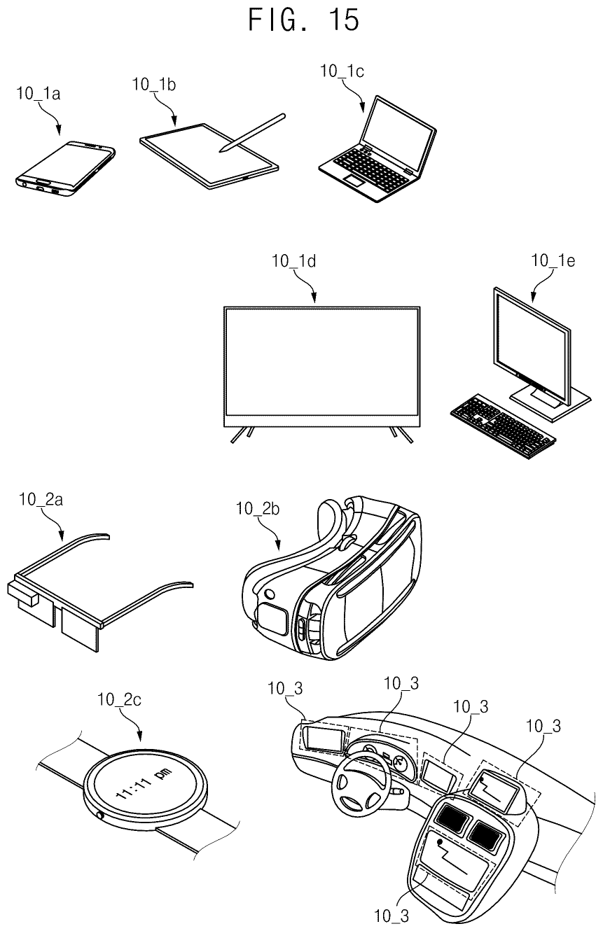

FIG. 14 is block-diagram for showing an electronic device according to an embodiment of the disclosure.

Referring to FIG. 1 and FIG. 14, the display device DD according to embodiments of present disclosure may be applied to various electronic devices 10. The electronic device 10 according to an embodiment may include the display device DD, and may further include a module or device including additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to generate power necessary for an operation of the electronic device 10.

At least one of the components of the electronic device 10 described above may be included in the display device according to embodiments described herein. In addition, some of individual modules functionally included in one module may be included in the display device, and other parts may be provided separately from the display device. For example, the display device DD may include the display module 11, and the processor 12, the memory 13, and the power module 14 may be provided in the form of other devices within the electronic device 10 other than the display device DD.

FIG. 15 is schematic views for showing the electronic device according to various embodiments of FIG. 14.

Referring to FIGS. 14 and 15, various electronic devices to which the display device DD according to embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (center information display) and a room mirror display placed on a dashboard, center fascia, or dashboard of an automobile.

However, this is exemplary, and the electronic device 10 according to embodiments of the present disclosure is not limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile.

While inventive concepts of the disclosure have been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a display panel having an exterior facing surface;
a first coating layer disposed on the display panel opposite the exterior facing surface and defining an opening;
a second coating layer disposed on the first coating layer and in the opening; and
a sensor part disposed on the second coating layer opposite the first coating layer.

2. The display device of claim 1, wherein the first coating layer has a first modulus, and
the second coating layer has a second modulus greater than the first modulus.

3. The display device of claim 2, wherein the second modulus is between about 1.2 times and about 10,000 times the first modulus.

4. The display device of claim 1, wherein the first coating layer includes at least one of an ultraviolet photoinitiator or a thermal initiator.

5. The display device of claim 1, wherein the second coating layer includes an ultraviolet photoinitiator.

6. The display device of claim 1, wherein a sidewall of the opening has an inclination in a cross-sectional view.

7. The display device of claim 1, wherein the opening has a trapezoidal shape in a cross-sectional view.

8. The display device of claim 1, wherein the opening in the first coating layer exposes a portion of the display panel; and
the second coating layer is disposed on the display panel exposed in the opening, and
wherein the opening includes:
a first opening surface disposed on the display panel and having a first area in a plan view; and
a second opening surface disposed opposite the first opening surface and having a second area larger than the first area in a plan view.

9. The display device of claim 1, further comprising a window layer disposed on the exterior facing surface of the display panel,
wherein the opening overlaps the sensor part in a plan view.

10. The display device of claim 1, wherein a planar area in which the first coating layer contacts the second coating layer is larger than a planar area in which the first coating layer contacts the display panel.

11. A display device comprising:
a window layer;
a display panel disposed on the window layer and including a plurality of sensor recognition areas;
a first coating layer disposed on a lower surface of the display panel opposite the window layer and defining a plurality of openings;
a second coating layer disposed on the first coating layer and in the plurality of openings; and
a plurality of sensor parts disposed on a lower surface of the second coating layer opposite the first coating layer and overlapping the plurality of openings in a plan view, respectively.

12. The display device of claim 11, wherein the first coating layer has a first modulus, and
the second coating layer has a second modulus greater than the first modulus.

13. The display device of claim 12, wherein the second modulus is between about 1.2 times and about 10,000 times the first modulus.

14. The display device of claim 11, wherein the first coating layer includes at least one of a first ultraviolet photoinitiator or a thermal initiator, and
the second coating layer includes a second ultraviolet photoinitiator.

15. The display device of claim 11, wherein a sidewall of each opening of the plurality of openings has an inclination in a cross-sectional view.

16. The display device of claim 11, wherein each opening of the plurality of openings includes:
a first opening surface disposed on the display panel and having a first area in a plan view; and
a second opening surface disposed opposite the first opening surface and having a second area larger than the first area in a plan view.

17. The display device of claim 11, wherein the plurality of openings overlap the plurality of sensor parts in a plan view respectively.

18. The display device of claim 11, wherein a planar area in which the first coating layer contacts the second coating layer is larger than a planar area in which the first coating layer contacts the display panel.

19. A display device comprising:
a display panel having an exterior facing surface;
a first coating layer having a first modulus and disposed on the display panel opposite the exterior facing surface and defining an opening exposing the display panel and having a sidewall having a slope in a cross-sectional view;
a second coating layer having a second modulus greater than the first modulus and disposed on the first coating layer and the display panel exposed in the opening; and
a sensor part disposed on the second coating layer opposite the first coating layer and overlapping the opening.

20. The display device of claim 19, wherein the opening includes:
a first opening surface disposed on the display panel and having a first area in a plan view; and
a second opening surface disposed opposite the first opening surface and having a second area larger than the first area in a plan view,
wherein the sensor part is a biometric sensor for detecting a characteristic of a finger of a user, and
the display device further comprises:
a printed circuit board disposed on the second coating layer opposite the first coating layer, wherein the printed circuit board is disposed outside of the second opening surface; and
a connection pattern electrically connecting the printed circuit board and the sensor part.

21. An electronic device comprising:
a display device; and
a processor configured to drive the display device, and
wherein the display device includes:
a display panel having an exterior facing surface;
a first coating layer disposed on the display panel opposite the exterior facing surface and defining an opening;
a second coating layer disposed on the first coating layer and in the opening; and
a sensor part disposed on the second coating layer opposite the first coating layer.
